(19) United States
(12) Patent Application Publication
(10) Pub. No.: US 2025/0347561 A1
(43) Pub. Date: Nov. 13, 2025

(54) DISPLAY DEVICE

(71) Applicant: Samsung Display Co., Ltd., Yongin-Si (KR)

(72) Inventors: Jun Hee CHOI, Yongin-si (KR); Kee Deok KIM, Yongin-si (KR); Chang Hwan KIM, Yongin-si (KR); Tae Ho KIM, Yongin-si (KR); Tae Hoon KIM, Yongin-si (KR); Han Eol SONG, Yongin-si (KR); Sang Ho YEO, Yongin-si (KR); Jin Kyeong OH, Yongin-si (KR); Young Shin LEE, Yongin-si (KR); Byeong Guk CHOI, Yongin-si (KR)

(21) Appl. No.: 18/934,246

(22) Filed: Nov. 1, 2024

(30) Foreign Application Priority Data
May 13, 2024 (KR) 10-2024-0062496

(51) Int. Cl. G01J 3/50; G01J 1/42; H10K 59/12; H10K 59/35; H10K 71/70

(52) U.S. Cl. CPC G01J 3/505; G01J 1/42; H10K 59/1201; H10K 71/70; G01J 2001/4252; H10K 59/35

(57) ABSTRACT

The present disclosure relates to an optical characteristic determination device, and particularly, to an optical characteristic determination device and an optical characteristic determination method for a display device that allow simple and fast determination of optical characteristics of the display device. According to an aspect of the present disclosure, there is provided an optical characteristic determination device for a display device, including: an optical measuring instrument irradiating a test element group (TEG) element that has the same configuration as a light emitting element of a substrate and measuring a reflectance of the TEG element based on the amount of light reflected from the TEG element; and a 10 processing unit determining optical characteristics of the TEG element based on the reflectance of the TEG element from the optical measuring instrument.

### CROSS-REFERENCE TO RELATED APPLICATION

This application claims priority from Korean Patent Application No. 10-2024-0062496 filed on May 13, 2024 in the Korean Intellectual Property Office, and all the benefits accruing therefrom under 35 U.S.C. § 119, the contents of which in its entirety are herein incorporated by reference.

### BACKGROUND

### 1. Technical Field

The present disclosure relates to an optical characteristic determination device, and particularly, to a device and method for determining the optical characteristics of a display device in a short period of time.

### 2. Description of the Related Art

An organic light emitting display apparatus includes display elements whose luminance is changed by a current, for example, organic light emitting diodes.

Such an organic light emitting display apparatus includes a plurality of pixels that provide light of different colors.

### SUMMARY

Aspects of the present disclosure provide an optical characteristic determination device and an optical characteristic determination method for a display device, which allow simple and quick determination of optical characteristics of the display device.

According to an aspect of the present disclosure, there is provided an optical characteristic determination device for a display device, including: an optical measuring instrument irradiating a test element group (TEG) element having the same configuration as a light emitting element of a substrate and measuring a reflectance of the TEG element based on an amount of light reflected from the TEG element; and a processing unit determining optical characteristics of the TEG element based on the reflectance of the TEG element from the optical measuring instrument.

The processing unit may provide the optical characteristics of the TEG element as optical characteristics of the light emitting element.

The optical characteristics of the TEG element may include at least one of color coordinates, luminous efficiency, white angular dependency (WAD), luminance, color coordinates for each viewing angle, and a color coordinate change amount for each viewing angle of the TEG element.

The processing unit may determine the optical characteristics of the TEG element by analyzing the reflectance of the TEG element using at least one of regression analysis and an artificial intelligence model.

The optical measuring instrument may include a spectroscopy reflectometer.

According to another aspect of the present disclosure, there is provided an optical characteristic determination method of a display device, including: forming a light emitting element and a TEG element on a substrate, forming the TEG element to have the same configuration as the light emitting element; measuring a reflectance of the TEG element; and determining optical characteristics of the TEG element based on the reflectance of the TEG element.

The measuring of the reflectance of the TEG element may include: irradiating the TEG element with light; and determining the reflectance of the TEG element based on light reflected from the TEG element and the light irradiated onto the TEG element.

The optical characteristic determination method of a display device may further include providing the optical characteristics of the TEG element as optical characteristics of the light emitting element.

The light emitting element and the TEG element may be formed through the same process.

The substrate may be a mother substrate including a plurality of display panels.

The light emitting elements may be formed on the plurality of display panels.

The TEG element may be formed on one side of the mother substrate excluding the plurality of display panels.

The light emitting element may include a first light emitting element, a second light emitting element, and a third light emitting element that provide light of different colors.

The TEG element may include: a first TEG element formed through the same process as the first light emitting element; a second TEG element formed through the same process as the second light emitting element; and a third TEG element formed through the same process as the third light emitting element.

Each of the first TEG element and the first light emitting element may include an organic light emitting layer providing light of a first color, each of the second TEG element and the second light emitting element may include an organic light emitting layer providing light of a second color, and each of the third TEG element and the third light emitting element may include an organic light emitting layer providing light of a third color.

Each of the first TEG element and the first light emitting element may further include a pixel electrode and a common electrode disposed with the organic light emitting layer of the first color interposed therebetween, each of the second TEG element and the second light emitting element may further include a pixel electrode and a common electrode disposed with the organic light emitting layer of the second color interposed therebetween, and each of the third TEG element and the third light emitting element may further include a pixel electrode and a common electrode disposed with the organic light emitting layer of the third color interposed therebetween.

The optical characteristics of the TEG element may include at least one of color coordinates, luminous efficiency, WAD, luminance, color coordinates for each viewing angle, and a color coordinate change amount for each viewing angle of the TEG element.

With a display device according to an exemplary embodiment, after reflectance of a TEG element having the same characteristics as a light emitting element is detected without supplying power to the light emitting element, optical characteristics of the light emitting element may be determined based on the reflectance of the TEG element. Accordingly, a cumbersome process such as supplying the power to the light emitting element to allow the light emitting element to emit light may be omitted. Accordingly, according to an exemplary embodiment, optical characteristics of the light emitting elements of a display panel may be determined in a short time period using a simple method. Accordingly, it is possible to perform an inspection on optical characteristics of all mother substrates.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view illustrating a display device according to an exemplary embodiment;

FIG. 2 is a cross-sectional view illustrating the display device according to an exemplary embodiment;

FIG. 3 is a plan view illustrating a display unit of the display device according to an exemplary embodiment;

FIG. 4 is a block diagram illustrating a display panel and a display driver according to an exemplary embodiment;

FIG. 5 is a circuit diagram of one pixel of the display device according to an exemplary embodiment;

FIG. 6 is a cross-sectional view of the display device according to an exemplary embodiment;

FIG. 7 is a plan view of a mother substrate including a plurality of display panels according to an exemplary embodiment;

FIG. 8 is a diagram illustrating a method of determining the optical characteristics of a display device using an optical characteristic determination device for a display device according to an exemplary embodiment;

FIG. 9 is graphs illustrating reflectance for each wavelength of light reflected from a third test element grout (TEG) element;

FIG. 10 is a flowchart for describing an optical characteristic determination method of the display device according to an exemplary embodiment;

FIG. 11 is a diagram for comparing and describing optical characteristics of a second TEG element determined according to the optical characteristic determination method of the display device according to an exemplary embodiment and optical characteristics of a second light emitting element driven by power with each other;

FIG. 12 is a diagram for comparing and describing optical characteristics of a third TEG element determined according to the optical characteristic determination method of the display device according to an exemplary embodiment and optical characteristics of a third light emitting element driven by power with each other; and

FIGS. 13 to 19 are cross-sectional views illustrating a structure of a light emitting element according to an exemplary embodiment.

### DETAILED DESCRIPTION OF THE EMBODIMENTS

The present invention will now be described more fully hereinafter with reference to the accompanying drawings, in which preferred embodiments are shown. This inventive concept may be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although ordinal terms “first”, “second”, etc. may be used herein to describe various elements, these elements should not be limited to any order or priority by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or in totality. As will be clearly appreciated by those skilled in the art, technically various interactions and operations are possible. Various embodiments can be practiced individually or in combination.

Hereinafter, specific exemplary embodiments will be described with reference to the accompanying drawings.

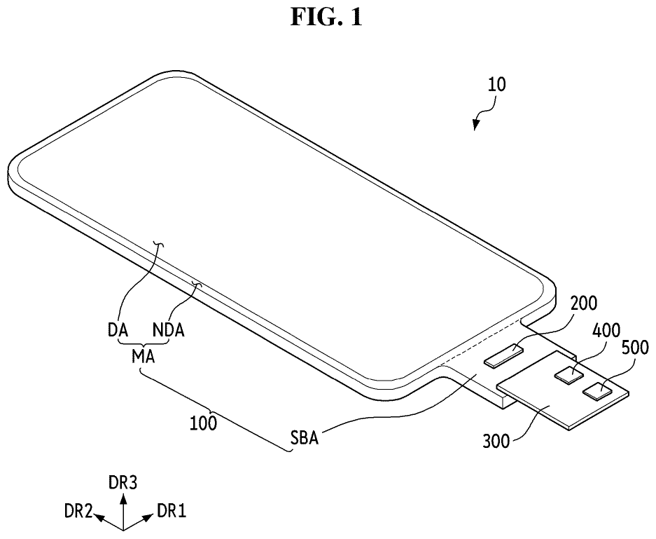

FIG. 1 is a perspective view illustrating a display device according to an exemplary embodiment.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be applied as a display unit of televisions, laptop computers, monitors, billboards, or the Internet of Things (IOTs). In another example, the display device 10 may be applied to wearable devices such as smart watches, watch phones, glasses-type displays, and head mounted displays (HMDs).

The display device 10 may have a shape similar to a rectangular shape in plan view. For example, the display device 10 may have a shape similar to a rectangular shape, in plan view, having short sides in a first direction DR1 and long sides in a second direction DR2. A corner where the short side in the first direction DR1 and the long side in the second direction DR2 meet may be rounded with a predetermined curvature or right-angled. The shape of the display device 10 in plan view is not limited to the rectangular shape, and may be a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels displaying an image and a non-display area NDA disposed around the display area DA. The display area DA may emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines and fan-out lines (not illustrated) connecting the display driver 200 and the display area DA to each other.

The sub-area SBA may extend from one side of the main area MA. The sub-area SBA may include a flexible material that may be bent, folded, and rolled. For example, when the sub-area SBA is bent, the sub-area SBA may overlap the main area MA in a thickness direction (e.g., a third direction DR3). The sub-area SBA may include the display driver 200 and pad portions connected to the circuit board 300. Alternatively, the sub-area SBA may be omitted, and the display driver 200 and the pad portions may be disposed in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. For example, the display driver 200 may be disposed in the sub-area SBA, and may overlap the main area MA in the thickness direction (third direction DR3) by bending of the sub-area SBA. In another example, the display driver 200 may be mounted on the circuit board 300.

The circuit board 300 may be attached onto the pad portions of the display panel 100 using an anisotropic conductive film (ACF). Lead lines of the circuit board 300 may be electrically connected to the pad portions of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply touch driving signals to a plurality of touch electrodes of the touch sensing unit and sense change amounts in capacitance between the plurality of touch electrodes. For example, the touch driving signal may be a pulse signal having a predetermined frequency. The touch driver 400 may decide whether or not an input has occurred and calculate input coordinates, based on the change amounts in capacitance between the plurality of touch electrodes. The touch driver 400 may be formed as an integrated circuit (IC).

The power supply unit 500 may be disposed on the circuit board 300 and may supply source voltages to the display driver 200 and the display panel 100. The power supply unit 500 may generate a first driving voltage and supply the first driving voltage to a driving voltage line VDL, may generate initialization voltages (e.g., a first initialization voltage and a second initialization voltage) and supply the initialization voltages to initialization voltage lines (e.g., a first initialization voltage line VIL1 and a second initialization voltage line VIL2), and may generate a common voltage and supply the common voltage to a common electrode common to light emitting elements of a plurality of pixels. For example, the first driving voltage may be a high potential voltage for driving the light emitting element, and the common voltage may be a low potential voltage for driving the light emitting element.

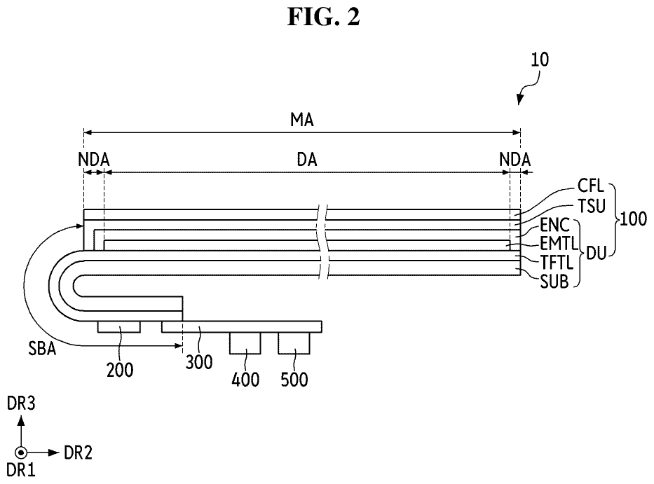

FIG. 2 is a cross-sectional view illustrating the display device according to an exemplary embodiment.

Referring to FIG. 2, the display panel 100 may include a display unit DU, a touch sensing unit TSU, and a color filter layer CFL. The display unit DU may include a substrate SUB, a thin film transistor layer TFTL, a light emitting element layer EMTL, and an encapsulation layer ENC.

The substrate SUB may be a base substrate or a base member. The substrate SUB may be a flexible substrate that may be bent, folded, and rolled. For example, the substrate SUB may include a polymer resin such as polyimide (PI), but is not limited thereto. In another example, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include gate lines, data lines, power lines, gate control lines, fan-out lines connecting the display driver 200 and the data lines to each other, and lead lines connecting the display driver 200 and the pad portions to each other. Each of the thin film transistors may include a semiconductor region, a source electrode, a drain electrode, and a gate electrode. For example, when a gate driver is formed on one side of the non-display area NDA of the display panel 100, the gate driver may include thin film transistors.

The thin film transistor layer TFTL may be disposed in the display area DA, the non-display area NDA, and the sub-area SBA. The thin film transistors of each of the pixels, the gate lines, the data lines, and the power lines of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EMTL may be disposed on the thin film transistor layer TFTL. The light emitting element layer EMTL may include a plurality of light emitting elements in which a pixel electrode, a light emitting layer, and a common electrode are sequentially stacked to emit light and a pixel defining film defining the pixels. The plurality of light emitting elements of the light emitting element layer EMTL may be disposed in the display area DA.

For example, the light emitting layer may be an organic light emitting layer including an organic material. The light emitting layer may include a hole transporting layer, an organic light emitting layer, and an electron transporting layer. When the pixel electrode receives a predetermined voltage through the thin film transistor of the thin film transistor layer TFTL and the common electrode receives a cathode voltage, holes and electrons may move to the organic light emitting layer through the hole transporting layer and the electron transporting layer, respectively, and may be combined with each other in the organic light emitting layer to emit light. For example, the pixel electrode may be an anode electrode and the common electrode may be a cathode electrode, but the present disclosure is not limited thereto.

In another example, the plurality of light emitting elements may include quantum dot light emitting diodes each including a quantum dot light emitting layer, inorganic light emitting diodes each including an inorganic semiconductor, or micro light emitting diodes.

The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL.

The touch sensing unit TSU may be disposed on the encapsulation layer ENC. The touch sensing unit TSU may include a plurality of touch electrodes for sensing a user's touch in a capacitance manner and touch lines connecting the plurality of touch electrodes and the touch driver 400 to each other. For example, the touch sensing unit TSU may sense the user's touch in a mutual capacitance manner or a self-capacitance manner.

In another example, the touch sensing unit TSU may be disposed on a separate substrate disposed on the display unit DU. In this case, the substrate supporting the touch sensing unit TSU may be a base member encapsulating the display unit DU.

The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters respectively corresponding to a plurality of emission areas. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the touch sensing unit TSU, the display device 10 may not require a separate substrate for the color filter layer CFL. Accordingly, a thickness of the display device 10 may be relatively decreased.

The sub-area SBA of the display panel 100 may extend from one side of the main area MA. The sub-area SBA may include a flexible material that may be bent, folded, and rolled. For example, when the sub-area SBA is bent, the sub-area SBA may overlap the main area MA in the thickness direction (third direction DR3). The sub-area SBA may include a display driver 200 and pad portions connected to a circuit board 300.

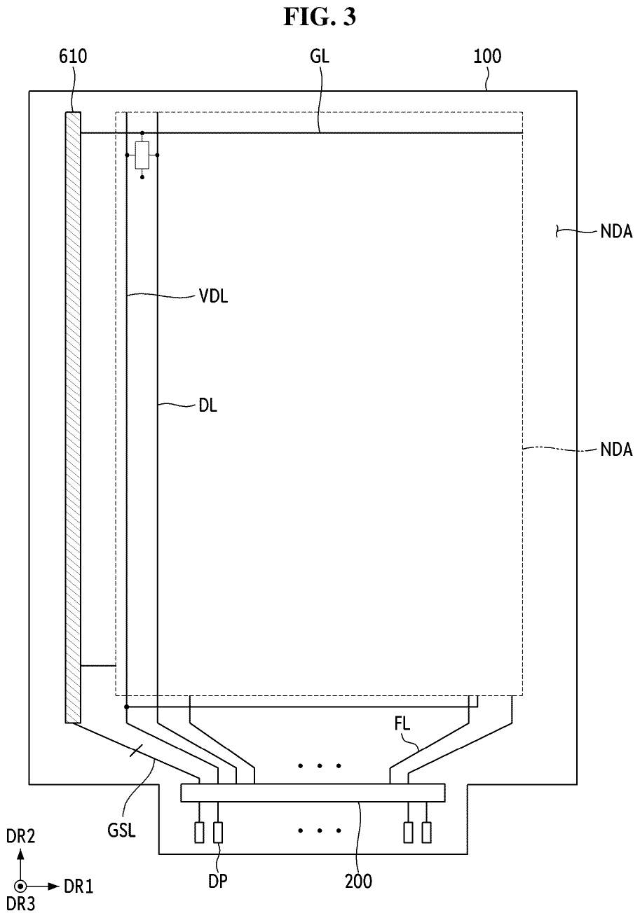

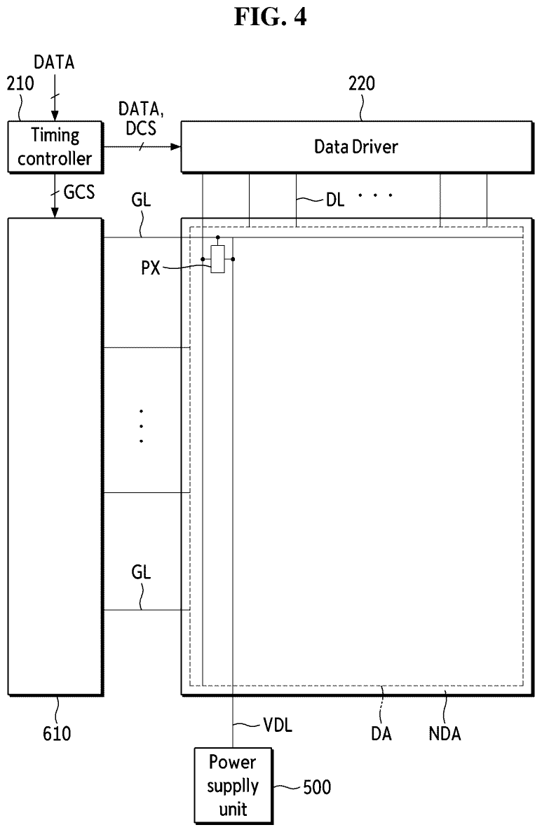

FIG. 3 is a plan view illustrating a display unit of the display device according to an exemplary embodiment, and FIG. 4 is a block diagram illustrating a display panel and a display driver according to an exemplary embodiment.

Referring to FIGS. 3 and 4, the display panel 100 may include a display area DA and a non-display area NDA.

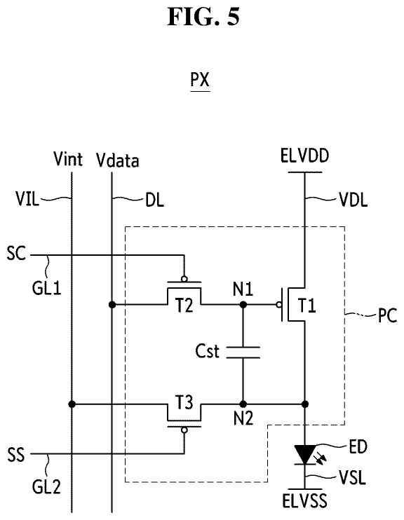

The display area DA may include a plurality of pixels PX, and a plurality of driving voltage lines VDL and a plurality of gate lines GL and a plurality of data lines DL of a plurality of common voltage lines VSL (see FIG. 5) that are connected to the plurality of pixels PX.

Each of the plurality of pixels PX may be connected to the gate line GL, the data line DL, the driving voltage line VDL, and the common voltage line VSL. Each of the plurality of pixels PX may include at least one transistor, a light emitting element, and a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the plurality of pixels PX.

The data lines DL may extend in the second direction DR2, and may be spaced apart from each other in the first direction DR1. The data lines DTL may be arranged along the first direction DR1. The data lines DL may supply data voltages to the plurality of pixels PX. The data voltage may determine luminance of each of the plurality of pixels PX.

The driving voltage lines VDL may extend in the second direction DR2, and may be spaced apart from each other in the first direction DR1. The driving voltage lines VDL may be arranged along the first direction DR1. The driving voltage lines VDL may supply driving voltages to the plurality of pixels PX. The driving voltage may be a high potential voltage for driving the light emitting elements of the pixels PX.

The non-display areas NDA may surround the display area DA. The non-display area NDA may include a gate driver 610, fan-out lines FL, and a gate control line GSL.

The fan-out lines FL may extend from the display driver 200 to the display area DA. The fan-out lines FL may supply the data voltages received from the display driver 200 to the plurality of data lines DL.

The gate control line GSL may extend from the display driver 200 to the gate driver 610. The gate control line GSL may supply a gate control signal GCS received from the display driver 200 to the gate driver 610.

The sub-area SBA may extend from one side of the non-display area NDA. The sub-area SBA may include the display driver 200 and pad portions DP. The pad portion DP may be disposed in an area between an edge of one side of the sub-area SBA and the display driver 200. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may control the timing of the operation of the data driver 220 by generating a data control signal DCS based on the timing signals, may control the timing of the operation of the gate driver 610 by generating the gate control signal GCS based on the timing signals, and may control the timing of the emission control driver 620 by generating an emission control signal ECS based on the timing signals. The timing controller 210 may supply the gate control signal GCS to the gate driver 610 through the gate control line GSL. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are supplied, and the selected pixels PX may receive the data voltages through the data lines DL.

The power supply unit 500 may be disposed on the circuit board 300, and may supply source voltages to the display driver 200 and the display panel 100. The power supply unit 500 may generate a first driving voltage and supply the first driving voltage to a driving voltage line VDL, may generate an initialization voltage and supply the initialization voltage to an initialization voltage line, and may generate a common voltage and supply the common voltage to a common electrode common to light emitting elements of the plurality of pixels. This common voltage may be applied to the common electrode through the common voltage line VSL.

The gate driver 610 may be disposed outside one side of the display area DA or on one side of the non-display area NDA, and the emission control driver 620 may be disposed outside the other side of the display area DA or on the other side of the non-display area NDA, but the present disclosure is not limited thereto. In another example, the gate driver 610 and the emission control driver 620 may be disposed on either one side or the other side of the non-display area NDA.

The gate driver 610 may include a plurality of transistors generating gate signals based on the gate control signal GCS. The transistors of the gate driver 610 may be formed at the same layer as transistors of each of the pixels PX. The gate driver 610 may supply the gate signals to the gate lines GL.

FIG. 5 is a circuit diagram of one pixel of the display device according to an exemplary embodiment.

Referring to FIG. 5, the pixel PX may be connected to a first gate line GL1, a second gate line GL2, a data line DL, and an initialization voltage line VIL.

The pixel PX may include a pixel circuit PC and the light emitting element ED.

The pixel circuit PC may include a first transistor T1, a second transistor T2, a third transistor T3, and a capacitor Cst.

The first transistor T1 may include a gate electrode, a source electrode, and a drain electrode. The first transistor T1 may control a source-drain current (hereinafter referred to as a driving current) according to a data voltage applied to the gate electrode. The driving current (e.g., Isd) flowing through a channel region of the first transistor T1 may be proportional to the square of a difference between a voltage Vsg between the source electrode and the gate electrode and a threshold voltage Vth of the first transistor T1 (Isd=k×(Vsg−Vth)²). Here, k refers to a proportional coefficient determined by a structure and physical properties of the first transistor T1, Vsg refers to a source-gate voltage of the first transistor T1, and Vth refers to the threshold voltage of the first transistor T1. The gate electrode of the first transistor T1 may be electrically connected to a first node N1, the drain electrode of the first transistor T1 may be electrically connected to the driving voltage line VDL, and the source electrode of the first transistor T1 may be electrically connected to a second node N2. The driving voltage line VDL may transmit a driving voltage ELVDD.

The light emitting element ED may emit light by receiving the driving current Isd. A light emission amount or luminance of the light emitting element ED may be proportional to a magnitude of the driving current Isd. The light emitting element ED may be an organic light emitting diode including a first electrode, a second electrode, and an organic light emitting layer disposed between the first electrode and the second electrode. In another example, the light emitting element ED may be an inorganic light emitting element including a first electrode, a second electrode, and an inorganic semiconductor disposed between the first electrode and the second electrode. As still another example, the light emitting element ED may be a quantum dot light emitting element including a first electrode, a second electrode, and a quantum dot light emitting layer disposed between the first electrode and the second electrode. As still another example, the light emitting element ED may be a micro light emitting diode. The first electrode of the light emitting element ED may be connected to the second node N2. The first electrode of the light emitting element ED may be connected to the source electrode of the first transistor T1, a drain electrode of the third transistor T3, and a second electrode of the capacitor Cst through the second node N2. The second electrode of the light emitting element ED may be connected to the common voltage line VSL. The second electrode of the light emitting element ED may receive a common voltage ELVSS (e.g., a low potential voltage) from the common voltage line VSL.

The second transistor T2 may be turned on by a first gate signal SC of the first gate line GL1 to electrically connect the data line DL and the first node N1, which is the gate electrode of the first transistor T1, to each other. The second transistor T2 may be turned on based on the first gate signal SC to supply a data voltage Vdata of the data line DL to the first node N1. A gate electrode of the second transistor T2 may be electrically connected to the first gate line GL1, a drain electrode of the second transistor T2 may be electrically connected to the data line DL, and a source electrode of the second transistor T2 may be electrically connected to the first node N1.

The third transistor T3 may be turned on by a second gate signal SS of the second gate line GL2 to electrically connect the initialization voltage line VIL and the second node N2, which is the first electrode of the light emitting element ED, to each other. The third transistor T3 may be turned on based on the second gate signal SS to supply an initialization voltage Vint of the initialization voltage line VIL to the second node N2. The initialization voltage Vint may have a smaller value than a threshold voltage of the light emitting element ED. A gate electrode of the third transistor T3 may be electrically connected to the second gate line GL2, a source electrode of the third transistor T3 may be electrically connected to the initialization voltage line VIL, and the drain electrode of the third transistor T3 may be electrically connected to the second node N2.

The capacitor Cst may be electrically connected between the first node N1, which is the gate electrode of the first transistor T1, and the second node N2, which is the source electrode of the first transistor T1. A first electrode of the capacitor Cst may be electrically connected to the first node N1, and the second electrode of the capacitor Cst may be electrically connected to the second node N2. For example, the capacitor Cst may store the data voltage Vdata supplied from the data line DL through the first transistor T1.

Each of the first transistor T1, the second transistor T2, and the third transistor T3 may include an oxide-based active layer. The oxide-based active layer may include, for example, indium gallium zinc oxide (IGZO) or indium gallium zinc tin oxide (IGZTO). The transistor including the oxide-based active layer may have a coplanar structure in which a gate electrode thereof is disposed at a top. The transistor including the oxide-based active layer may correspond to an n-type transistor, and may output a current introduced into a drain electrode to a source electrode based on a gate high voltage applied to the gate electrode.

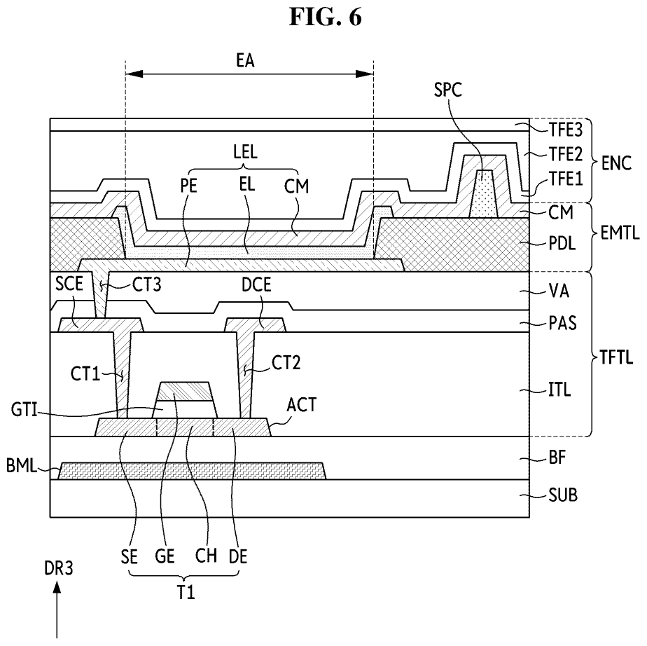

FIG. 6 is a cross-sectional view of the display device according to an exemplary embodiment.

The display device according to the present disclosure may include a substrate SUB, a light blocking layer BML, a buffer film BF, a thin film transistor layer TFTL, a light emitting element layer EMTL, and an encapsulation layer ENC, as illustrated in FIG. 6. The light blocking layer BML, the buffer film BF, the thin film transistor layer TFTL, the light emitting element layer EMTL, and the encapsulation layer ENC may be sequentially disposed on the substrate SUB along the third direction DR3. Here, the thin film transistor layer TFTL may include the first transistor T1, the second transistor T2, and the third transistor T3 described above with reference to FIG. 5. In FIG. 6, the first transistor T1 included in the thin film transistor layer TFTL is illustrated as an example.

The substrate SUB may be a rigid substrate or be a flexible substrate that may be bent, folded, and rolled. The substrate SUB may be made of an insulating material such as glass, quartz, or a polymer resin. Examples of the polymer resin may include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or combinations thereof. Alternatively, the substrate SUB may include a metal material.

The light blocking layer BML may be disposed on the substrate SUB. The light blocking layer BML may be disposed on the substrate SUB so as to overlap an active layer ACT to be described later. The light blocking layer BML may be made of a metal material such as chromium (Cr) or molybdenum (Mo), black ink, black dye, or the like. Meanwhile, when the light blocking layer BML is made of the metal material, the light blocking layer BML may receive constant power. Accordingly, the light blocking layer BML may not be electrically floated, and electrical characteristics of the transistors T1, T2, and T3 on the light blocking layer BML may be stabilized. For example, performance deterioration of the oxide-based transistors T1, T2, and T3 may be minimized. Meanwhile, oxide semiconductors are sensitive to light, such that fluctuations in current amount or the like in the oxide semiconductors may occur by light from the outside.

The buffer film BF may be disposed on the light blocking layer BML. The buffer film BF may be disposed on the entire surface of the substrate SUB including the light blocking layer BML. The buffer film BF may be a film for protecting the transistors of the thin film transistor layer TFTL and light emitting layers EL of the light emitting element layer EMTL from moisture permeating through the substrate SUB vulnerable to moisture permeation. The buffer film BF may include a plurality of inorganic films that are alternately stacked. For example, the buffer film BF may be formed as multiple films in which one or more inorganic films of a silicon nitride layer, a silicon oxynitride layer, a silicon oxide layer, a titanium oxide layer, and an aluminum oxide layer are alternately stacked.

The active layer ACT may be disposed on the buffer film BF. The active layer ACT may be an oxide semiconductor. For example, the active layer ACT may be a semiconductor including indium gallium zinc oxide (IGZO) or indium gallium zinc tin oxide (IGZTO).

A gate insulating film GTI may be disposed on the active layer ACT. For example, the gate insulating film GTI may be disposed to overlap a channel region CH of the active layer ACT. The gate insulating film GTI may include at least one of tetraethylorthosilicate (TEOS), silicon nitride (SiNₓ), and silicon oxide (SiO₂). For example, the gate insulating film GTI may have a double-film structure in which a silicon nitride film having a thickness of 40 nm and a TEOS film having a thickness of 80 nm are sequentially stacked.

A gate electrode GE may be disposed on the gate insulating film GTI. The gate electrode GE may be disposed on the gate insulating film GTI so as to overlap the channel region CH of the active layer ACT. The gate electrode GE may be made of aluminum (Al), titanium (Ti), or the like. In addition, the gate electrode GE may have a double-film or triple-film structure in which aluminum (Al) and titanium (Ti) are stacked.

An interlayer insulating film ITL may be disposed on the gate electrode GE. The interlayer insulating film ITL may be disposed on the entire surface of the substrate SUB including the gate electrode GE. The interlayer insulating film ITL may include an inorganic film such as a silicon nitride layer, a silicon oxynitride layer, a silicon oxide layer, a titanium oxide layer, or an aluminum oxide layer. Meanwhile, the interlayer insulating film ITL may include a plurality of inorganic films.

A source connection electrode SCE and a drain connection electrode DCE may be disposed on the interlayer insulating film ITL. The source connection electrode SCE may be connected to a source electrode SE of the active layer ACT through a first contact hole CT1 penetrating through the interlayer insulating film ITL. The drain connection electrode DCE may be connected to a drain electrode DE of the active layer ACT through a second contact hole CT2 penetrating through the interlayer insulating film ITL. The source connection electrode SCE and the drain connection electrode DCE may be made of the same material as the gate electrode described above.

A passivation film PAS may be disposed on the source connection electrode SCE and the drain connection electrode DCE. The passivation film PAS may be disposed on the entire surface of the substrate SUB including the interlayer insulating film ITL. The passivation film PAS may be made of the same material as the interlayer insulating film ITL.

A planarization film VA may be disposed on the passivation film PAS. The planarization film VA may be disposed on the entire surface of the substrate SUB including the passivation film PAS. The planarization film VA may include an organic film made of an acrylic resin, an epoxy resin, a phenolic resin, a polyamide resin, a polyimide resin, or the like.

The light emitting element layer EMTL including a pixel electrode PE may be disposed on the planarization film VA. The pixel electrode PE may be connected to the source connection electrode SCE through a third contact hole CT3 penetrating through the planarization film VA. The pixel electrode PE may be connected to the source electrode SE of the active layer ACT through the source connection electrode SCE.

The light emitting element layer EMTL described above may further include a light emitting element ED and a bank PDL (or a pixel defining film) in addition to the pixel electrode PE described above.

The light emitting element ED may include the pixel electrode PE, the light emitting layer EL, and a common electrode CM. An emission area EA refers to an area where the pixel electrode PE, the light emitting layer EL, and the common electrode CM are sequentially stacked and holes from the pixel electrode PE and electrons from the common electrode CM are combined with each other in the light emitting layer to emit light. In this case, the pixel electrode PE may be an anode electrode of the light emitting element ED, and the common electrode CM may be a cathode electrode of the light emitting element ED.

In a top emission structure in which light is emitted toward the common electrode CM based on the light emitting layer EL, the pixel electrode PE may be formed as a single layer made of molybdenum (Mo), titanium (Ti), copper (Cu), or aluminum (Al) or formed as a stacked structure (Ti/Al/Ti) of aluminum and titanium, a stacked structure (ITO/AI/ITO) of aluminum and indium tin oxide (ITO), an APC alloy, and a stacked structure (ITO/APC/ITO) of an APC alloy and ITO in order to increase reflectance. The APC alloy is an alloy of silver (Ag), palladium (Pd), and copper (Cu).

The bank PDL (or the pixel defining film) serves to define the emission areas EA of the pixel. To this end, the bank PDL may be disposed to expose a partial area of the pixel electrode PE on the planarization film VA. The bank PDL may cover an edge of the pixel electrode PE. The bank PDL may be formed as an organic film made of an acrylic resin, an epoxy resin, a phenolic resin, a polyamide resin, a polyimide resin, or the like.

A spacer SPC may be disposed on the bank PDL. The spacer SPC may serve to support a mask during a process of manufacturing the light emitting layer EL. The spacer SPC may be formed as an organic film made of an acrylic resin, an epoxy resin, a phenolic resin, a polyamide resin, a polyimide resin, or the like.

The light emitting layer EL may be formed on the pixel electrode PE. The light emitting layer EL may include an organic material to emit light of a predetermined color. For example, the light emitting layer EL may include a hole transporting layer, an organic material layer, and an electron transporting layer. The organic material layer may include a host and a dopant. The organic material layer may include a material emitting predetermined light, and may be formed using a phosphorescent material or a fluorescent material.

The plurality of pixels may include a first pixel emitting light of a first color through a first emission area, a second pixel emitting light of a second color through a second emission area, and a third pixel emitting light of a third color through a third emission area.

An organic material layer of a first light emitting layer of the first emission area emitting the light of the first color (e.g., red) may be made of a phosphorescent material including a host material including carbazole biphenyl (CBP) or 1,3-bis(carbazol-9-yl) (mCP) and including a dopant including one or more selected among bis(1-phenylisoquinoline) acetylacetonate iridium (PIQIr(acac)), bis(1-phenylquinoline) acetylacetonate iridium (PQIr(acac)), tris(1-phenylquinoline)iridium (PQIr), and platinum octaethylporphyrin (PtOEP). Alternatively, the organic material layer of the first light emitting layer of the first emission area may be made of a fluorescent material including PBD: Eu(DBM)₃(Phen) or perylene, but is not limited thereto.

An organic material layer of a second light emitting layer of the second emission area emitting the light of the second color (e.g., green) may be made of a phosphorescent material including a host material including CBP or mCP and including a dopant material including fac-tris(2-phenylpyridine) iridium (Ir(ppy)3). Alternatively, the organic material layer of the second light emitting layer of the second emission area emitting the light of the second color may be made of a fluorescent material including tris(8-hydroxyquinolino)aluminum (Alq3), but is not limited thereto.

An organic material layer of a third light emitting layer of the third emission area emitting the light of the third color (e.g., blue) may be made of a phosphorescent material including a host material including CBP or mCP and including a dopant material including (4,6-F2ppy)2Irpic or L2BD111, but is not limited thereto.

The common electrode CM may be disposed on the light emitting layer EL. For example, the common electrode CM may be disposed on the first, second, and third light emitting layers. The common electrode CM may be disposed to cover the first, second, and third light emitting layers. The common electrode CM may be a common layer disposed in common on the first to third light emitting layers. A capping layer may be formed on the common electrode CM.

In the top emission structure, the common electrode CM may be made of a transparent conductive material (TCO) such as ITO or indium zinc oxide (IZO) capable of transmitting light therethrough or a semi-transmissive conductive material such as magnesium (Mg), silver (Ag), or an alloy of magnesium (Mg) and silver (Ag). When the common electrode CM is made of the semi-transmissive conductive material, emission efficiency may be increased by a micro cavity.

The encapsulation layer ENC may be formed on the light emitting element layer EMTL. The encapsulation layer ENC may include at least one inorganic film TFE1 and TFE3 in order to prevent oxygen or moisture from permeating into the light emitting element layer EMTL. In addition, the encapsulation layer ENC may include at least one organic film in order to protect the light emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like.

Meanwhile, a barrier film may be further disposed between the substrate SUB and the light blocking layer BML described above. The barrier film may be a film for protecting the transistors T1 to T3 of the thin film transistor layer TFTL and the light emitting layers EL of the light emitting element layer EMTL from moisture permeating through the substrate SUB vulnerable to moisture permeation. The barrier film may include a plurality of inorganic films that are alternately stacked. For example, the barrier film may be formed as multiple films in which one or more inorganic films of a silicon nitride layer, a silicon oxynitride layer, a silicon oxide layer, a titanium oxide layer, and an aluminum oxide layer are alternately stacked.

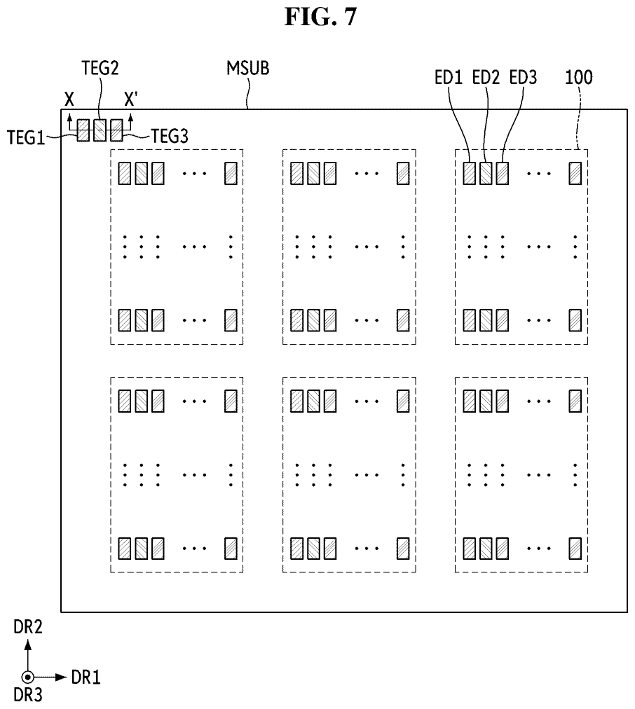

FIG. 7 is a plan view of a mother substrate including a plurality of display panels 100 according to an exemplary embodiment.

A mother substrate MSUB may include the plurality of display panels 100.

The display panel 100 may include a plurality of light emitting elements. The plurality of light emitting elements may include a first light emitting element ED1, a second light emitting element ED2, and a third light emitting element ED3 that provide light of different colors. For example, the first light emitting element ED1 may provide light of a first color, the second light emitting element ED2 may provide light of a second color, and the third light emitting element ED3 may provide light of a third color. Here, the first color may be red, the second color may be green, and the third color may be blue.

The mother substrate MSUB may be cut in a cell processing step. By cutting the mother substrate MSUB, the plurality of display panels 100 may be manufactured from the mother substrate MSUB.

Test element group (TEG) elements may be disposed on one side of the mother substrate MSUB. For example, a first TEG element TEG1, a second TEG element TEG2, and a third TEG element TEG3 may be disposed on the mother substrate MSUB.

The first TEG element TEG1 may have the same configuration as the first light emitting element ED1 of the display panel 100. The first TEG element TEG1 may be formed through the same process as the first light emitting element ED1. The first TEG element TEG1 and the first light emitting element ED1 may be formed simultaneously through the same process. Accordingly, the first TEG element TEG1 and the first light emitting element ED1 may be substantially the same element. For example, each of the first TEG element TEG1 and the first light emitting element ED1 may include an organic light emitting layer capable of providing the light of the first color. In addition, each of the first TEG element TEG1 and the first light emitting element ED1 may further include a pixel electrode PE and a common electrode CM in addition to the organic light emitting layer of the first color. In this case, the pixel electrode PE and the common electrode CM of the first TEG element TEG1 may be disposed with the organic light emitting layer of the first color interposed therebetween, and the pixel electrode PE and the common electrode CM of the first light emitting element ED1 may be disposed with the organic light emitting layer of the first color interposed therebetween.

The second TEG element TEG2 may have the same configuration as the second light emitting element ED2 of the display panel 100. The second TEG element TEG2 may be formed through the same process as the second light emitting element ED2. The second TEG element TEG2 and the second light emitting element ED2 may be formed simultaneously through the same process. Accordingly, the second TEG element TEG2 and the second light emitting element ED2 may be substantially the same element. For example, each of the second TEG element TEG2 and the second light emitting element ED2 may include an organic light emitting layer capable of providing the light of the second color. In addition, each of the second TEG element TEG2 and the second light emitting element ED2 may further include a pixel electrode PE and a common electrode CM in addition to the organic light emitting layer of the second color. In this case, the pixel electrode PE and the common electrode CM of the second TEG element TEG2 may be disposed with the organic light emitting layer of the second color interposed therebetween, and the pixel electrode PE and the common electrode CM of the second light emitting element ED2 may be disposed with the organic light emitting layer of the second color interposed therebetween.

The third TEG element TEG3 may have the same configuration as the third light emitting element ED3 of the display panel 100. The third TEG element TEG3 may be formed through the same process as the third light emitting element ED3. The third TEG element TEG3 and the third light emitting element ED3 may be formed simultaneously through the same process. Accordingly, the third TEG element TEG3 and the third light emitting element ED3 may be substantially the same element. For example, each of the third TEG element TEG3 and the third light emitting element ED3 may include an organic light emitting layer capable of providing the light of the third color. In addition, each of the third TEG element TEG3 and the third light emitting element ED3 may further include a pixel electrode PE and a common electrode CM in addition to the organic light emitting layer of the third color. In this case, the pixel electrode PE and the common electrode CM of the third TEG element TEG3 may be disposed with the organic light emitting layer of the third color interposed therebetween, and the pixel electrode PE and the common electrode CM of the third light emitting element ED3 may be disposed with the organic light emitting layer of the third color interposed therebetween.

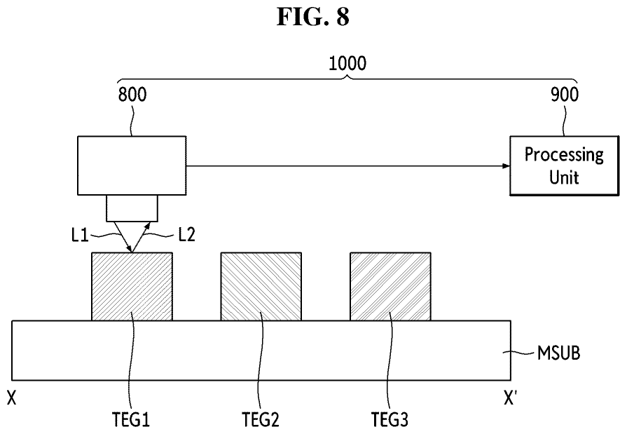

According to an exemplary embodiment, reflectance of each of the first TEG element TEG1, the second TEG element TEG2, and the third TEG element TEG3 may be measured in order to determine the optical characteristics (e.g., color coordinates, luminous efficiency, white angular dependency (WAD), luminance, color coordinates for each viewing angle, and a color coordinate change amount for each viewing angle) of each of the first light emitting element ED1, the second light emitting element ED2, and the third light emitting element ED3. The optical characteristics of the first light emitting element ED1 may be determined based on the reflectance of the first TEG element TEG1, the optical characteristics of the second light emitting element ED2 may be determined based on the reflectance of the second TEG element TEG2, and the optical characteristics of the third light emitting element ED3 may be determined based on the reflectance of the third TEG element TEG3. This will be described in detail below with reference to FIG. 8.

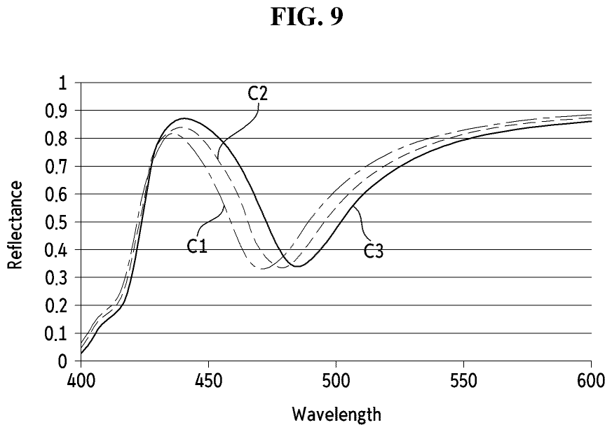

FIG. 8 is a diagram illustrating a method of determining optical characteristics of a display device 10 using an optical characteristic determination device 1000 for a display device according to an exemplary embodiment. A cross-sectional view of a mother substrate, a first TEG element, a second TEG element, and a third TEG element in FIG. 8 is a cross-sectional view of the mother substrate, the first TEG element, the second TEG element, and the third TEG element taken along line X-X′ in FIG. 7. FIG. 9 is graphs illustrating reflectance for each wavelength of light reflected from a third TEG element TEG3.

In order to determine the optical characteristics of the display device 10, the optical characteristic determination device 1000 for a display device may be prepared, as illustrated in FIG. 8.

The optical characteristic determination device 1000 for a display device according to an exemplary embodiment may include an optical measuring instrument 800 and a processing unit 900.

The optical measuring instrument 800 may determine the optical characteristics of the display device 10, for example, optical characteristics of a light emitting element provided in the display device 10. For example, the optical measuring instrument 800 may detect reflectance (e.g., spectral reflectance) of the light emitting element. Here, the spectral reflectance refers to reflectance of light of a predetermined wavelength, and spectral reflectance measurement technology refers to technology that detects optical characteristics or a thickness of a specimen (e.g., a light emitting element or a TEG element) by comparing an amount of light reflected for each wavelength from the specimen with an amount of incident light to measure and analyze reflectance of the specimen for each wavelength. The optical measuring instrument 800 according to an exemplary embodiment may include a spectroscopy reflectometer. “Light,” as used herein, includes visible light but does not exclude wavelengths outside the visible range.

First, the optical measuring instrument 800 may be positioned above the first TEG element TEG1 to determine the optical characteristics of the first TEG element TEG1, as shown in FIG. 8. Light L1 emitted from the optical measuring instrument 800 may be incident on the first TEG element TEG1. The light L1 incident on the first TEG element TEG1 may be reflected from the first TEG element TEG1 and incident on the optical measuring instrument 800. The optical measuring instrument 800 may detect reflectance (e.g., spectral reflectance) of the first TEG element TEG1 based on the incident light L1 provided to the first TEG element TEG1 and the reflected light L2 reflected from the first TEG element TEG1. For example, the optical measuring instrument 800 may detect the reflectance of the first TEG element TEG1 by comparing an amount of light reflected for each wavelength (e.g., the light L2 reflected for each wavelength from the first TEG element TEG1) with an amount of incident light (e.g., the light L1 incident on the first TEG element TEG1 from the optical measuring instrument 800) to measure and analyze reflectance (e.g., spectral reflectance) of the first TEG element TEG1 for each wavelength.

Subsequently, the optical measuring instrument 800 may be positioned above the second TEG element TEG2 to determine the optical characteristics of the second TEG element TEG2. Light emitted from the optical measuring instrument 800 may be incident on the second TEG element TEG2. The light incident on the second TEG element TEG2 may be reflected from the second TEG element TEG2 and incident on the optical measuring instrument 800. The optical measuring instrument 800 may detect reflectance (e.g., spectral reflectance) of the second TEG element TEG2 based on the incident light provided to the second TEG element TEG2 and the reflected light reflected from the second TEG element TEG2. For example, the optical measuring instrument 800 may detect the optical characteristics of the second TEG element TEG2 by comparing an amount of light reflected for each wavelength (e.g., the light reflected for each wavelength from the second TEG element TEG2) with an amount of incident light (e.g., the light incident on the second TEG element TEG2 from the optical measuring instrument 800) to measure and analyze reflectance (e.g., spectral reflectance) of the second TEG element TEG2 for each wavelength.

Subsequently, the optical measuring instrument 800 may be positioned above the third TEG element TEG3 to determine the optical characteristics of the third TEG element TEG3. Light emitted from the optical measuring instrument 800 may be incident on the third TEG element TEG3. The light incident on the third TEG element TEG3 may be reflected from the third TEG element TEG3 and incident on the optical measuring instrument 800. The optical measuring instrument 800 may detect reflectance (e.g., spectral reflectance) of the third TEG element TEG3 based on the incident light provided to the third TEG element TEG3 and the reflected light reflected from the third TEG element TEG3. For example, the optical measuring instrument 800 may detect the optical characteristics of the third TEG element TEG3 by comparing an amount of light reflected for each wavelength (e.g., the light reflected for each wavelength from the third TEG element TEG3) with an amount of incident light (e.g., the light incident on the third TEG element TEG3 from the optical measuring instrument 800) to measure and analyze reflectance (e.g., spectral reflectance) of the third TEG element TEG3 for each wavelength.

With the reflectance of the first TEG element TEG1, the reflectance of the second TEG element TEG2, and the reflectance of the third TEG element TEG3 detected as described above, the optical characteristics of each of the TEG elements TEG1, TEG2, and TEG3 may be determined. For example, optical characteristics may include color coordinates, luminous efficiency, WAD, luminance, color coordinates for each viewing angle, and a color coordinate change amount for each viewing angle. The optical characteristics of the first TEG element TEG1 may be determined based on the reflectance of the first TEG element TEG1, the optical characteristics of the second TEG element TEG2 may be determined based on the reflectance of the second TEG element TEG2, and the optical characteristics of the third TEG element TEG3 may be determined based on the reflectance of the third TEG element TEG3.

Optical characteristics of the TEG element may be determined based on a result calculated as a product between an emission spectrum of a material (e.g., an organic light emitting layer) included in the TEG element and a resonance (or film thickness) spectrum of the TEG element. The resonance spectrum of the TEG element has characteristics that it is proportional to reflectance of the TEG element. For example, the resonance spectrum of the TEG element and the reflectance of the TEG element may be changed in the same direction depending on a film thickness of the TEG element. For example, as illustrated in FIG. 9, a characteristic curve indicating reflectance of blue light may tend to shift to the right as a film thickness of the third TEG element TEG3 increases. For example, in FIG. 9, a first characteristic curve C1 indicates reflectance for each wavelength for the third TEG element TEG3 of a first thickness, a second characteristic curve C2 indicates reflectance for each wavelength for the third TEG element TEG3 of a second thickness, and a third characteristic curve C3 indicates reflectance for each wavelength for the third TEG element TEG3 of a third thickness. Here, the second thickness is greater than the first thickness and smaller than the third thickness. In addition, color coordinates of the third TEG element TEG3 of the second thickness may be greater than color coordinates of the third TEG element TEG3 of the first thickness and smaller than color coordinates of the third TEG element TEG3 of the third thickness. A characteristic curve of the resonance spectrum may also tend to shift to the right as the thickness of the TEG element increases.

Accordingly, when the reflectance of the TEG element is detected by the optical measuring instrument 800, the resonance spectrum of the TEG element may be determined based on the reflectance. Meanwhile, the emission spectrum of the material included in the TEG element is determined by characteristics of the material, and may have an almost fixed value as long as the material does not change. Therefore, as described above, once the reflectance of the TEG element is detected, the optical characteristics of the TEG element may be determined.

According to an exemplary embodiment, the reflectance of the first TEG element TEG1, the reflectance of the second TEG element TEG2, and the reflectance of the third TEG element TEG3 detected from the optical measuring instrument 800 may be input to the processing unit 900 of the optical characteristic determination device. For example, the reflectance for each wavelength as illustrated in FIG. 9 may be input to the processing unit 900. The processing unit 900 may determine the optical characteristics of the first TEG element TEG1 based on the reflectance of the first TEG element TEG1, determine the optical characteristics of the second TEG element TEG2 based on the reflectance of the second TEG element TEG2, and determine the optical characteristics of the third TEG element TEG3 based on the reflectance of the third TEG element TEG3. For example, the processing unit 900 may determine the optical characteristics of the corresponding TEG element by analyzing the reflectance of the corresponding TEG element using at least one of regression analysis and an artificial intelligence model.

According to an exemplary embodiment, the processing unit 900 may be implemented with a memory that stores data on an algorithm for controlling operations of components in the present device (e.g., the optical characteristic determination device 1000 for a display device) or a program reproducing the algorithm and at least one processor (not illustrated) that performs the above-described operations using the data stored in the memory. In this case, the memory and the processor may each be implemented as separate chips. Alternatively, the memory and the processor may be implemented as a single chip. The processor may control at least one other component (e.g., a hardware or software component) of the optical measuring instrument 800 connected to the processor and perform various data processing or computations, by executing, for example, software (e.g., a program).

According to an exemplary embodiment, the processor may include a hardware structure specialized for processing an artificial intelligence model. The artificial intelligence model may be generated through machine learning. For example, such learning may be performed in the processing unit 900 itself where the artificial intelligence model is performed or may be performed through a separate server. A learning algorithm may include, for example, supervised learning, unsupervised learning, semi-supervised learning, or reinforcement learning, but is not limited thereto. The artificial intelligence model may include a plurality of artificial neural network layers. An artificial neural network may be one of a deep neural networks (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The artificial intelligence model may additionally or alternatively include a software structure in addition to a hardware structure.

When the optical characteristics of the first TEG element TEG1, the optical characteristics of the second TEG element TEG2, and the optical characteristics of the third TEG element TEG3 are determined in the manner as described above, optical characteristics of the first light emitting element ED1, optical characteristics of the second light emitting element ED2, and optical characteristics of the third light emitting element ED3 may be determined. For example, the first TEG element TEG1 may correspond to the first light emitting element ED1, meaning the first TEG element TEG1 and the first light emitting element ED1 have substantially the same configuration (e.g., the same material, the same film thickness, etc.) such that the optical characteristics of the first TEG element TEG1 may be assumed to represent the optical characteristics of the first light emitting element ED1. In other words, the optical characteristics of the first TEG element TEG1 may be used as a proxy for the optical characteristics of the first light emitting element ED1. In addition, the second TEG element TEG2 may correspond to the second light emitting element ED2, meaning the second TEG element TEG2 and the second light emitting element ED2 have substantially the same configuration (e.g., the same material, the same film thickness, etc.) such that the optical characteristics of the second TEG element TEG2 may be assumed to represent the optical characteristics of the second light emitting element ED2. In other words, the optical characteristics of the second TEG element TEG2 may be used as a proxy for the optical characteristics of the second light emitting element ED2. In addition, the third TEG element TEG3 and the third light emitting element ED3 have substantially the same configuration (e.g., the same material, the same film thickness, etc.) such that the optical characteristics of the third TEG element TEG3 may represent the optical characteristics of the third light emitting element ED3. In other words, the optical characteristics of the third TEG element TEG3 may be used as a proxy for the optical characteristics of the third light emitting element ED3.

According to an exemplary embodiment, after the reflectance of the TEG element having the same characteristics as the light emitting element ED is detected without supplying power to the light emitting element, the optical characteristics of the light emitting element may be determined based on the reflectance of the TEG element. Accordingly, a cumbersome process such as supplying power to the light emitting element to allow the light emitting element to emit light may be omitted. Accordingly, according to an exemplary embodiment, the optical characteristics of the light emitting elements of the display panel 100 may be determined in a fairly short time using a simple method. For example, in a comparative example in which the optical characteristics of the light emitting element is determined by supplying power to the light emitting element, determination of optical characteristics takes about 50 minutes. In comparison, an exemplary embodiment in accordance with the present disclosure allows the optical characteristics of the light emitting element to be determined based on the reflectance of the TEG element in about 10 seconds. According to an exemplary embodiment, the optical characteristic determination may be made in quickly as described above, and accordingly, it is possible to perform an inspection on the entire mother substrates MSUB. For example, a comparative example may take a sampling inspection having a measurement cycle of 50 cuts (e.g., a sampling inspection that inspects one of 50 mother substrates MSUB), while the present disclosure according to an exemplary embodiment may achieve a total inspection with a measurement cycle of one cut (for example, a total inspection that individually inspects all mother substrates MSUB).

According to an exemplary embodiment, the optical characteristics of the TEG element may also be determined based on transmittance instead of reflectance.

According to an exemplary embodiment, the optical measuring instrument 800 may include an ellipsometer. In such a case, the optical characteristics of the TEG element may be determined based on a polarization change amount between polarized light provided from the ellipsometer to the TEG element and light reflected from the TEG element and reflectance.

According to an exemplary embodiment, at least one of the first TEG element TEG1, the second TEG element TEG2, and the third TEG element TEG3 may be disposed in the non-display area NDA of the display panel 100. For example, the first TEG element TEG1, the second TEG element TEG2, and the third TEG element TEG3 may be disposed in the non-display area NDA of the display panel 100.

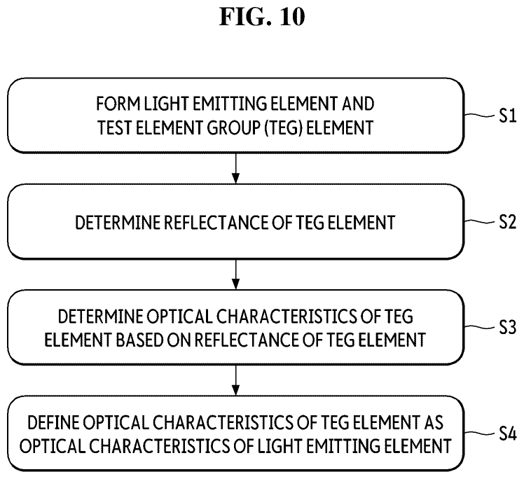

FIG. 10 is a flowchart for describing an optical characteristic determination method of the display device 10 according to an exemplary embodiment.

First, the first light emitting element ED1, the second light emitting element ED2, the third light emitting element ED3, the first TEG element TEG1, the second TEG element TEG2, and the third TEG element TEG3 may be formed on the mother substrate MSUB (S1). Here, the first light emitting element ED1 and the first TEG element TEG1 may be formed together using the same material, the second light emitting element ED2 and the second TEG element TEG2 may be formed together using the same material, and the third light emitting element ED3 and the third TEG element TEG3 may be formed together using the same material.

Subsequently, the reflectance of each TEG element may be detected (S2). For example, the reflectance of the first TEG element TEG1, the reflectance of the second TEG element TEG2, and the reflectance of the third TEG element TEG3 may be detected. The reflectance of each TEG element may be detected by, for example, the optical measuring instrument 800.

Next, the optical characteristics of each TEG element may be determined based on each detected reflectance (S3). For example, the optical characteristics of the first TEG element TEG1 may be determined based on the reflectance of the first TEG element TEG1, the optical characteristics of the second TEG element TEG2 may be determined based on the reflectance of the second TEG element TEG2, and the optical characteristics of the third TEG element TEG3 may be determined based on the reflectance of the third TEG element TEG3.

Thereafter, the optical characteristics of the first TEG element TEG1 may be treated as, and defined as, the optical characteristics of the first light emitting element ED1. Similarly, the optical characteristics of the second TEG element TEG2 may be treated as, and defined as, the optical characteristics of the second light emitting element ED2. Similarly, the optical characteristics of the third TEG element TEG3 may be treated as, and defined as, the optical characteristic of the third light emitting element ED3 (S4).

With the optical characteristics of the light emitting element determined as described above, a decision of whether or not the detected optical characteristics of the light emitting element satisfy preset reference optical characteristics may be made. In this case, when the optical characteristics of the light emitting element are out of a preset reference optical characteristic range (e.g., when the determined color coordinates of the light emitting element is out of a range of preset reference color coordinates), a process of modifying a thickness of the corresponding light emitting element may be further performed.

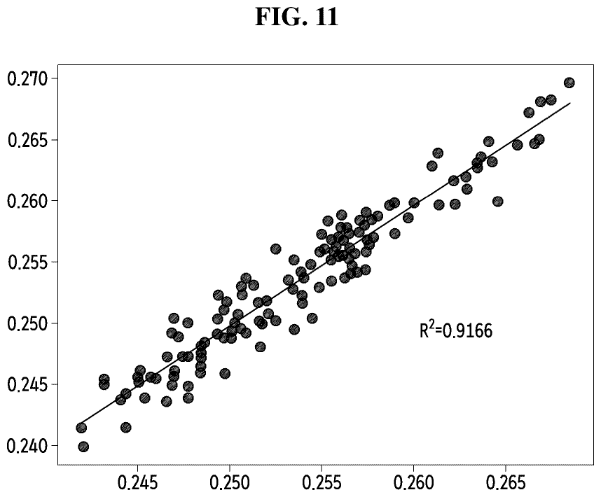

FIG. 11 is a diagram for optical characteristics of a second TEG element TEG2 that is determined using the optical characteristic determination method of the display device 10 according to an exemplary embodiment and optical characteristics of a second light emitting element ED2.

In FIG. 11, the horizontal X-axis indicates color coordinates of the second light emitting element ED2 emitting light with power applied thereto, and a vertical Y-axis indicates color coordinates of the second TEG element TEG2 determined according to the optical characteristic determination method according to an exemplary embodiment. For example, the Y-axis indicates the color coordinates of the second TEG element TEG2 determined based on the reflectance of the second TEG element TEG2.

As can be seen in FIG. 11, a regression curve for the color coordinates of the X-axis and the color coordinates of the Y-axis is linear. Accordingly, the color coordinates of the second light emitting element ED2 corresponding to the second TEG element TEG2 may be predicted from the color coordinates of the second TEG element TEG2 that are determined based on the reflectance of the second TEG element TEG2. In other words, the color coordinates of the second TEG element TEG2 that are determined based on the reflectance of the second TEG element TEG2 may be viewed as representing the color coordinates of the second light emitting element ED2.

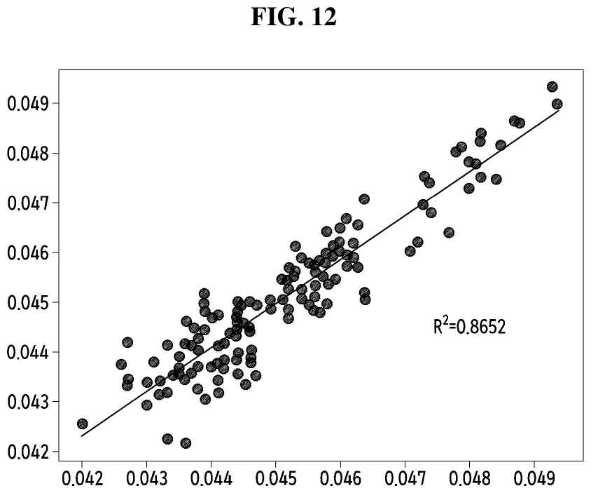

FIG. 12 is a diagram for optical characteristics of a third TEG element TEG3 determined by using the optical characteristic determination method of the display device 10 according to an exemplary embodiment and optical characteristics of a third light emitting element ED3.

In FIG. 12, the horizontal X-axis indicates color coordinates of the third light emitting element ED3 emitting light with power applied thereto, and the vertical Y-axis indicates color coordinates of the third TEG element TEG3 determined by using the optical characteristic determination method according to an exemplary embodiment. For example, the Y-axis indicates the color coordinates of the third TEG element TEG3 determined based on the reflectance of the third TEG element TEG3.

As can be seen in FIG. 12, a regression curve for the color coordinates of the X-axis and the color coordinates of the Y-axis is linear. Accordingly, the color coordinates of the third light emitting element ED3 corresponding to the third TEG element TEG3 may be predicted from the color coordinates of the third TEG element TEG3 determined based on the reflectance of the third TEG element TEG3. In other words, the color coordinates of the third TEG element TEG3 determined based on the reflectance of the third TEG element TEG3 may be treated as representing the color coordinates of the third light emitting element ED3.

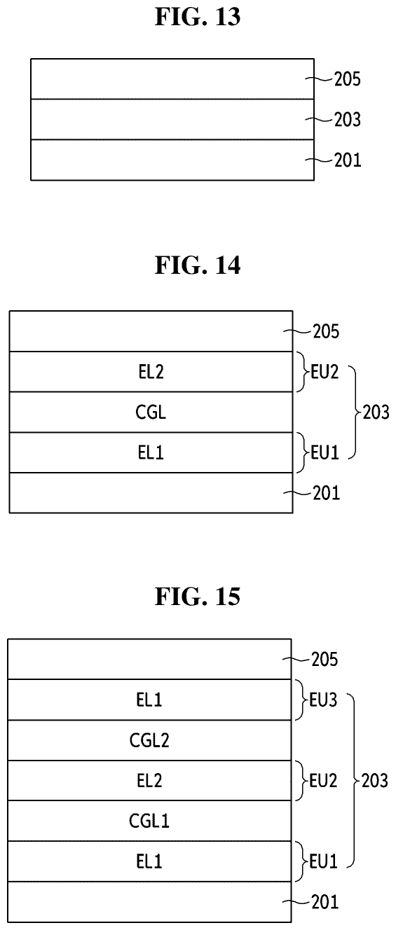

FIGS. 13 to 19 are cross-sectional views illustrating a structure of a light emitting element according to an exemplary embodiment.

Referring to FIG. 13, a light emitting element (e.g., an organic light emitting diode) according to an exemplary embodiment may include a pixel electrode 201, a common electrode 205, and an intermediate layer 203 between the pixel electrode 201 and the common electrode 205 described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. For example, the pixel electrode 201 may have a three-layer structure of ITO/Ag/ITO.

The common electrode 205 may be disposed on the intermediate layer 203. The common electrode 205 may include a metal having a low work function, an alloy, a electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The intermediate layer 203 may include a high molecular or low molecular organic material emitting light of a predetermined color. The intermediate layer 203 may further include a metal-containing compound such as an organometallic compound, an inorganic material such as quantum dots, and the like, in addition to various organic materials.

In an exemplary embodiment, the intermediate layer 203 may include one light emitting layer and a first functional layer and a second functional layer respectively disposed below and above the one light emitting layer. The first functional layer may include, for example, a hole transport layer (HTL) or a hole transport layer and a hole injection layer (HIL). The second functional layer is a component disposed above the light emitting layer and is optional. For example, the intermediate layer 203 may or may not include the second functional layer. The second functional layer may include an electron transport layer (ETL) and/or an electron injection layer (EIL).

In an exemplary embodiment, the intermediate layer 203 may include two or more light emitting units sequentially stacked between the pixel electrode 201 and the common electrode 205 and a charge generation layer CGL disposed between the two light emitting units. When the intermediate layer 203 includes the light emitting units and the charge generation layer, the light emitting element (e.g., the organic light emitting diode) may be a tandem light emitting element. The light emitting element (e.g., the organic light emitting diode) may improve color purity and luminous efficiency by having a stacked structure of a plurality of light emitting units.

One light emitting unit may include a light emitting layer and a first functional layer and a second functional layer respectively disposed below and above the light emitting layer. The charge generation layer CGL may include a negative charge generation layer and a positive charge generation layer. The luminous efficiency of the organic light emitting diode, which is the tandem light emitting element including a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In an exemplary embodiment, as illustrated in FIG. 14, the light emitting element (e.g., the organic light emitting diode) may include a first light emitting unit EU1 including a first light emitting layer EL1 and a second light emitting unit EU2 including a second light emitting layer EL2 that are sequentially stacked. A charge generation layer CGL may be disposed between the first light emitting unit EU1 and the second light emitting unit EU2. For example, the light emitting element (e.g., the organic light emitting diode) may include the pixel electrode 201, the first light emitting layer EL1, the charge generation layer CGL, the second light emitting layer EL2, and the common electrode 205 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an exemplary embodiment, as illustrated in FIG. 15, the light emitting element (e.g., the organic light emitting diode) may include a first light emitting unit EU1 and a third light emitting unit EU3 each including a first light emitting layer EL1 and a second light emitting unit EU2 including a second light emitting layer EL2. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. For example, the light emitting element (e.g., the organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an exemplary embodiment, in the light emitting element (e.g., the organic light emitting diode), the second light emitting unit EU2 may further include a third light emitting layer EL3 and/or a fourth light emitting layer EL4 in direct contact with the second light emitting layer EL2 below and/or above the second light emitting layer EL2 in addition to the second light emitting layer EL2. Here, the phrase “direct contact” may mean that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

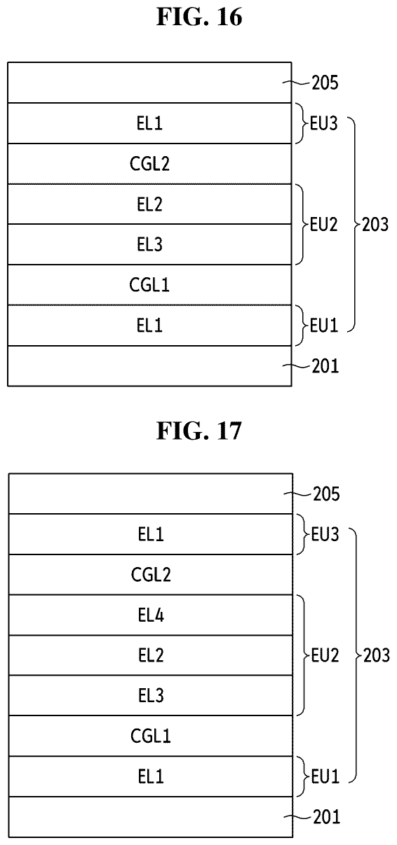

For example, as illustrated in FIG. 16, the light emitting element (e.g., the organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 17, the light emitting element (e.g., the organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 that are sequentially stacked.

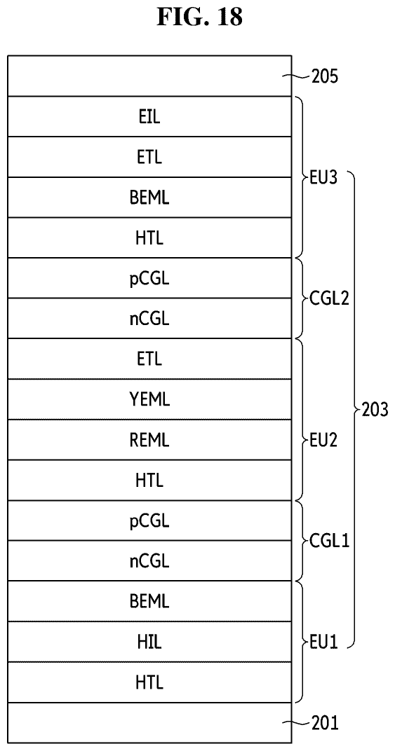

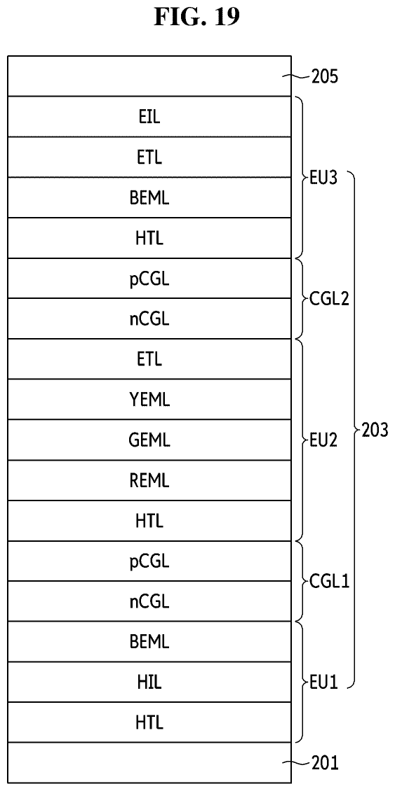

FIG. 18 is a cross-sectional view illustrating an example of the organic light emitting diode of FIG. 16, and FIG. 19 is a cross-sectional view illustrating an example of the organic light emitting diode of FIG. 17.

Referring to FIG. 18, the light emitting element (e.g., the organic light emitting diode) may include a first light emitting unit EU1, a second light emitting unit EU2, and a third light emitting unit EU3 that are sequentially stacked. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. Each of the first charge generation layer CGL1 and the second charge generation layer CGL2 may include a negative charge generation layer nCGL and a positive charge generation layer pCGL.

The first light emitting unit EU1 may include a blue light emitting layer BEML. The first light emitting unit EU1 may further include a hole injection layer HIL and a hole transport layer HTL between the pixel electrode 201 and the blue light emitting layer BEML. In an exemplary embodiment, a p-doped layer may be further included between the hole injection layer HIL and the hole transport layer HTL. The p-doped layer may be formed by doping the hole injection layer HIL with a p-type doping material. In an exemplary embodiment, at least one of a blue light auxiliary layer, an electron blocking layer, and a buffer layer may be further included between the blue light emitting layer BEML and the hole transport layer HTL. The blue light auxiliary layer may increase emission efficiency of the blue light emitting layer BEML. The blue light auxiliary layer may increase emission efficiency of the blue light emitting layer BEML by adjusting hole charge balance. The electron blocking layer may prevent injection of electrons into the hole transport layer HTL. The buffer layer may compensate for a resonance distance according to a wavelength of light emitted from the light emitting layer.

The second light emitting unit EU2 may include a yellow light emitting layer YEML and a red light emitting layer REML in direct contact with the yellow light emitting layer YEML below the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the yellow light emitting layer YEML and the negative charge generation layer nCGL of the second charge generation layer CGL2.

The third light emitting unit EU1 may include a blue light emitting layer BEML. The third light emitting unit EU3 may further include a hole transport layer HTL between the positive charge generation layer pCGL of the second charge generation layer CGL2 and the blue light emitting layer BEML. The third light emitting unit EU3 may further include an electron transport layer ETL and an electron injection layer EIL between the blue light emitting layer BEML and the common electrode 205. The electron transport layer ETL may be a single layer or multiple layers. In an exemplary embodiment, at least one of a blue light auxiliary layer, an electron blocking layer, and a buffer layer may be further included between the blue light emitting layer BEML and the hole transport layer HTL. At least one of a hole blocking layer and a buffer layer may be further included between the blue light emitting layer BEML and the electron transport layer ETL. The hole blocking layer may prevent injection of holes into the electron transport layer ETL.

The light emitting element (e.g., the organic light emitting diode) illustrated in FIG. 19 is different from the light emitting element (e.g., the organic light emitting diode) illustrated in FIG. 18 in the layers of the second light emitting unit EU2, and is the same as the light emitting element (e.g., the organic light emitting diode) illustrated in FIG. 18 in other configurations.

Meanwhile, the display panel 100 of the display device 10 may further include a capping layer disposed outside the common electrode 205. The capping layer may serve to improve luminous efficiency by the principle of constructive interference. Consequently, light extraction efficiency of the light emitting element (e.g., the organic light emitting diode) may be increased, such that the luminous efficiency of the light emitting element (e.g., the organic light emitting diode) may be improved.

According to an exemplary embodiment, the TEG element may have the same configuration as any one of the light emitting elements described above with reference to FIGS. 13 to 19. For example, when the first light emitting element has a structure as illustrated in FIG. 18, the first TEG element corresponding to the first light emitting element may also have the structure as illustrated in FIG. 18.

However, the effects of the present disclosure are not limited to the one set forth herein. The above and other effects of the present disclosure will become more apparent to one of daily skill in the art to which the present disclosure pertains by referencing the claims.

It should be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. The scope of the present disclosure are defined by the claims rather than the detailed description described above and all modifications and alterations derived from the claims and their equivalents fall within the scope of the present disclosure.

What is claimed is:

1. An optical characteristic determination device for a display device, comprising:
an optical measuring instrument irradiating a test element group (TEG) element having the same configuration as a light emitting element of a substrate and measuring a reflectance of the TEG element based on an amount of light reflected from the TEG element; and
a processing unit determining optical characteristics of the TEG element based on the reflectance of the TEG element from the optical measuring instrument.

2. The optical characteristic determination device for a display device of claim 1, wherein the processing unit provides the optical characteristics of the TEG element as optical characteristics of the light emitting element.

3. The optical characteristic determination device for a display device of claim 1, wherein the optical characteristics of the TEG element include at least one of color coordinates, luminous efficiency, white angular dependency (WAD), luminance, color coordinates for each viewing angle, and a color coordinate change amount for each viewing angle of the TEG element.

4. The optical characteristic determination device for a display device of claim 1, wherein the processing unit determines the optical characteristics of the TEG element by analyzing the reflectance of the TEG element using at least one of regression analysis and an artificial intelligence model.

5. The optical characteristic determination device for a display device of claim 1, wherein the optical measuring instrument includes a spectroscopy reflectometer.

6. An optical characteristic determination method of a display device, comprising:
forming a light emitting element and a TEG element on a substrate, forming the TEG element to have the same configuration as the light emitting element;
measuring a reflectance of the TEG element; and
determining optical characteristics of the TEG element based on the reflectance of the TEG element.

7. The optical characteristic determination method of a display device of claim 6, wherein the measuring of the reflectance of the TEG element includes:
irradiating the TEG element with light; and
determining the reflectance of the TEG element based on light reflected from the TEG element and the light irradiated onto the TEG element.

8. The optical characteristic determination method of a display device of claim 6, further comprising providing the optical characteristics of the TEG element as optical characteristics of the light emitting element.

9. The optical characteristic determination method of a display device of claim 6, wherein the light emitting element and the TEG element are formed through the same process.

10. The optical characteristic determination method of a display device of claim 6, wherein the measuring of the reflectance of the TEG element includes determining the optical characteristics of the TEG element by analyzing the reflectance of the TEG element using at least one of regression analysis and an artificial intelligence model.

11. The optical characteristic determination method of a display device of claim 6, wherein the substrate is a mother substrate including a plurality of display panels.

12. The optical characteristic determination method of a display device of claim 11, wherein the light emitting elements are formed on the plurality of display panels.

13. The optical characteristic determination method of a display device of claim 11, wherein the TEG element is formed on one side of the mother substrate excluding the plurality of display panels.

14. The optical characteristic determination method of a display device of claim 6, wherein the light emitting element includes a first light emitting element, a second light emitting element, and a third light emitting element that provide light of different colors.

15. The optical characteristic determination method of a display device of claim 14, wherein the TEG element includes:
a first TEG element formed through the same process as the first light emitting element;
a second TEG element formed through the same process as the second light emitting element; and
a third TEG element formed through the same process as the third light emitting element.

16. The optical characteristic determination method of a display device of claim 15, wherein each of the first TEG element and the first light emitting element includes an organic light emitting layer providing light of a first color,
each of the second TEG element and the second light emitting element includes an organic light emitting layer providing light of a second color, and
each of the third TEG element and the third light emitting element includes an organic light emitting layer providing light of a third color.

17. The optical characteristic determination method of a display device of claim 16, wherein each of the first TEG element and the first light emitting element further includes a pixel electrode and a common electrode disposed with the organic light emitting layer of the first color interposed therebetween,
each of the second TEG element and the second light emitting element further includes a pixel electrode and a common electrode disposed with the organic light emitting layer of the second color interposed therebetween, and
each of the third TEG element and the third light emitting element further includes a pixel electrode and a common electrode disposed with the organic light emitting layer of the third color interposed therebetween.

18. The optical characteristic determination method of a display device of claim 6, wherein the optical characteristics of the TEG element include at least one of color coordinates, luminous efficiency, WAD, luminance, color coordinates for each viewing angle, and a color coordinate change amount for each viewing angle of the TEG element.

19. The optical characteristic determination method of a display device of claim 6, wherein the measuring of the reflectance of the TEG element comprises using an optical measuring instrument.

20. The optical characteristic determination method of a display device of claim 19, wherein the optical measuring instrument includes a spectroscopy reflectometer.
